(19) United States
(12) Patent Application Publication
(10) Pub. No.: US 2026/0136538 A1
(43) Pub. Date: May 14, 2026

(54) THREE-DIMENSIONAL SEMICONDUCTOR DEVICES AND METHODS FOR MANUFACTURING THE SAME

(71) Applicant: Samsung Electronics Co., Ltd., Suwon-si (KR)

(72) Inventors: Hyebin KIM, Suwon-si (KR); Jinwoo HAN, Suwon-si (KR); Eunsuk JANG, Suwon-si (KR); Woochul KIM, Suwon-si (KR); Jihoon CHOI, Suwon-si (KR)

(21) Appl. No.: 19/174,021

(22) Filed: Apr. 9, 2025

(30) Foreign Application Priority Data
Nov. 12, 2024 (KR) 10-2024-0160477

(51) Int. Cl. H10B 12/00; G11C 5/06

(52) U.S. Cl. CPC H10B 12/482; G11C 5/063; H10B 12/315; H10B 12/488

(57) ABSTRACT

A three-dimensional semiconductor device may include first semiconductor patterns spaced apart from each other in a first direction; second semiconductor patterns that are spaced apart from the first semiconductor patterns in a second direction and are spaced apart from each other in the first direction; first bit lines on the first semiconductor patterns; second bit lines on the second semiconductor patterns; and a shielding pattern between the first and second bit lines in the second direction, wherein the shielding pattern includes first regions and second regions, the first regions are between the first and second bit lines in the second direction, at least one of the second regions is between respective adjacent ones of the first regions in the first direction, and a width of the second regions in the second direction is greater than a width of the first regions in the second direction.

### CROSS-REFERENCE TO RELATED APPLICATIONS

This U.S. non-provisional patent application claims priority under 35 U.S.C. § 119 of Korean Patent Application No. 10-2024-0160477, filed on Nov. 12, 2024, the entire contents of which are hereby incorporated by reference.

### BACKGROUND OF THE INVENTION

The present disclosure herein relates to three-dimensional semiconductor devices and methods for manufacturing the same, and more particularly, to three-dimensional semiconductor devices with improved productivity and electrical characteristics.

A semiconductor device is attracting attention as an important component in the electronics industry due to characteristics thereof such as miniaturization, multi-functionality, and/or low manufacturing cost. The semiconductor device may be classified into a semiconductor memory device that stores a logic data, a semiconductor logic device that calculates and processes the logic data, and a hybrid semiconductor device that includes a memory component and a logic component.

Recently, with a high speed and low power consumption of an electronic apparatus, a high operation speed, a low operation voltage and/or the like are/is also needed for the semiconductor device built therein. In order to satisfy such needs a highly-integrated semiconductor device may be needed. However, when the semiconductor device becomes highly-integrated, electrical characteristics and production yield of the semiconductor device may be compromised (e.g., reduced). Accordingly, much research for improving the electrical characteristics and the production yield of the semiconductor device is being carried out.

### SUMMARY OF THE INVENTION

The present disclosure may provide three-dimensional semiconductor devices with improved electrical characteristics and reliability and methods for manufacturing the same.

A technical goal of the inventive concept is not limited to the goal mentioned above, and other technical goals that are not mentioned may be clearly understood from description below by those skilled in the art.

An embodiment of the inventive concept provides a three-dimensional semiconductor device including a substrate; first semiconductor patterns on the substrate, wherein the first semiconductor patterns are spaced apart from each other in a first direction that is parallel to an upper surface of the substrate; second semiconductor patterns on the substrate, wherein the second semiconductor patterns are spaced apart from the first semiconductor patterns in a second direction that is parallel to the upper surface of the substrate and intersects the first direction, and wherein the second semiconductor patterns are spaced apart from each other in the first direction; first bit lines on edge portions of the first semiconductor patterns; second bit lines on edge portions of the second semiconductor patterns, wherein the edge portions of the second semiconductor patterns face the edge portions of the first semiconductor patterns in the second direction; and a shielding pattern between the first bit lines and the second bit lines in the second direction, wherein the shielding pattern includes first regions and second regions, wherein the first regions of the shielding pattern are between the first bit lines and the second bit lines in the second direction, wherein at least one of the second regions of the shielding pattern is between respective adjacent ones of the first regions of the shielding pattern in the first direction, and wherein a width of the at least one of the second regions of the shielding pattern in the second direction is greater than a width of at least one of the first regions of the shielding pattern in the second direction.

In an embodiment of the inventive concept, a three-dimensional semiconductor device includes a substrate; first semiconductor patterns on the substrate, wherein the first semiconductor patterns are spaced apart from each other in a first direction that is parallel to an upper surface of the substrate; second semiconductor patterns on the substrate, wherein the second semiconductor patterns are spaced apart from the first semiconductor patterns in a second direction that is parallel to the upper surface of the substrate and intersects the first direction, and wherein the second semiconductor patterns are spaced apart from each other in the first direction; first bit lines on edge portions of the first semiconductor patterns; second bit lines on edge portions of the second semiconductor patterns, wherein the edge portions of the second semiconductor patterns face the edge portions of the first semiconductor patterns in the second direction; and a shielding pattern between the first bit lines and the second bit lines in the second direction, wherein the shielding pattern includes first regions and second regions, wherein the first regions of the shielding pattern are between the first bit lines and the second bit lines in the second direction, wherein at least one of the second regions of the shielding pattern is between adjacent ones of the first regions of the shielding pattern in the first direction, and wherein the at least one of the second regions of the shielding pattern is between respective adjacent ones of the first bit lines in the first direction.

In an embodiment of the inventive concept, a three-dimensional semiconductor device includes a substrate; first semiconductor patterns on the substrate, wherein the first semiconductor patterns are spaced apart from each other in a first direction that is parallel to an upper surface of the substrate; second semiconductor patterns on the substrate, wherein the second semiconductor patterns are spaced apart from the first semiconductor patterns in a second direction that is parallel to the upper surface of the substrate and intersects the first direction, and wherein the second semiconductor patterns are spaced apart from each other in the first direction; first bit lines on first edge portions of the first semiconductor patterns, wherein the first bit lines extend in a third direction that is perpendicular to the upper surface of the substrate; second bit lines on first edge portions of the second semiconductor patterns, wherein the second bit lines extend in the third direction, and wherein the first edge portions of the second semiconductor patterns face the first edge portions of the first semiconductor patterns in the second direction; a word line that extends around at least one of the first semiconductor patterns, wherein the word line extends in the first direction; a data storage pattern on second edge portions of the first semiconductor patterns, wherein the data storage pattern extends in the third direction, and wherein the second edge portions of the first semiconductor patterns are opposite to the first edge portions of the first semiconductor patterns in the second direction; and a shielding pattern between the first bit lines and the second bit lines in the second direction, wherein the shielding pattern includes first regions and second regions, wherein the first regions of the shielding pattern are between the first bit lines and the second bit lines in the second direction, wherein at least one of the second regions of the shielding pattern is between respective adjacent ones of the first regions of the shielding pattern in the first direction, and where a width of the at least one of the second regions of the shielding pattern in the second direction is greater than a width of at least one of the first regions of the shielding pattern in the second direction.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain the inventive concept. In the drawings:

FIG. 1 is a schematic circuit diagram illustrating a three-dimensional semiconductor device according to some embodiments of the inventive concept;

FIGS. 2A, 2B and 2C are schematic perspective views of a three-dimensional semiconductor device according to some embodiments of the inventive concept;

FIG. 3 is a plan view of a three-dimensional semiconductor device according to some embodiments of the inventive concept;

FIG. 4 is a cross-sectional view corresponding to line A-A′ of FIG. 3;

FIG. 5 is an enlarged diagram corresponding to PI of FIG. 3;

FIG. 6 is a cross-sectional view corresponding to line A-A′ of FIG. 3;

FIG. 7 is a plan view of a three-dimensional semiconductor device according to some embodiments of the inventive concept;

FIG. 8 is a cross-sectional view corresponding to line A-A′ of FIG. 7;

FIG. 9 is a cross-sectional view corresponding to line A-A′ of FIG. 7;

FIGS. 10 to 18 are diagrams illustrating a method for manufacturing a three-dimensional semiconductor device according to some embodiments of the inventive concept; and

FIG. 19 is a diagram illustrating a method for manufacturing a three-dimensional semiconductor device according to some embodiments of the inventive concept.

### DETAILED DESCRIPTION

Hereinafter, embodiments of the inventive concept will be described in more detail with reference to the accompanying drawings in order to specifically describe the inventive concept.

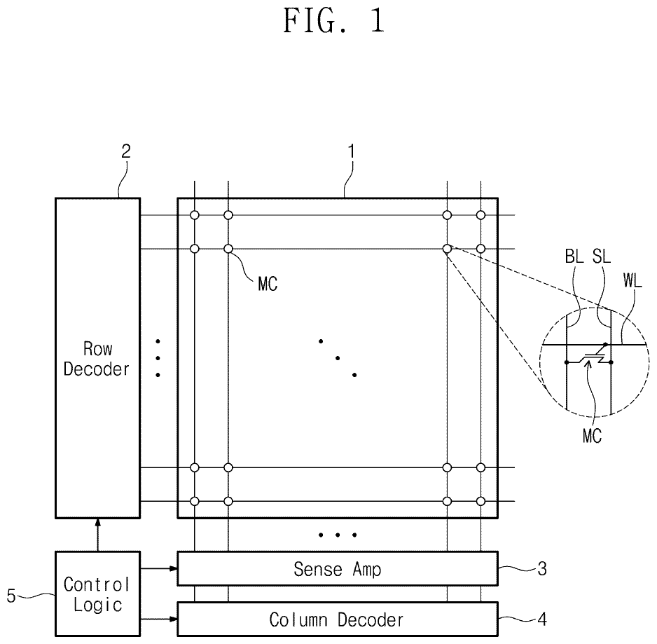

FIG. 1 is a schematic circuit diagram illustrating a three-dimensional semiconductor device according to some embodiments of the inventive concept.

Referring to FIG. 1, the three-dimensional semiconductor device may include a memory cell array 1, a row decoder 2, a sense amplifier 3, a column decoder 4 and a control logic 5.

The memory cell array 1 may include word lines WL, bit lines BL, source lines SL and memory cells MC. The memory cells MC may be three-dimensionally arranged, and the memory cell MC may be (electrically) connected to one word line WL, one bit line BL, and one source line SL. According to some embodiments, each of the memory cells MC may be composed of one transistor including a memory layer (or data storage layer).

The row decoder 2 may decode an address input from the outside, and may select any one among the word lines WL of the memory cell array 1. The address decoded by the row decoder 2 may be provided to a row driver (not shown), and the row driver may provide a selected word line WL and unselected word lines WL with a predetermined voltage in response to controlling of control circuits. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

The sense amplifier 3 may sense, amplify and output a voltage difference between a bit line BL selected according to an address decoded by the column decoder 4 and a reference bit line.

The column decoder 4 may provide a data transfer path between the sense amplifier 3 and an external device (for example, a memory controller). The column decoder 4 may select any one among the bit lines BL by decoding an address input from the outside.

The control logic 5 may generate control signals that control operations of writing a data to the memory cell array 1 or reading the data from the memory cell array 1.

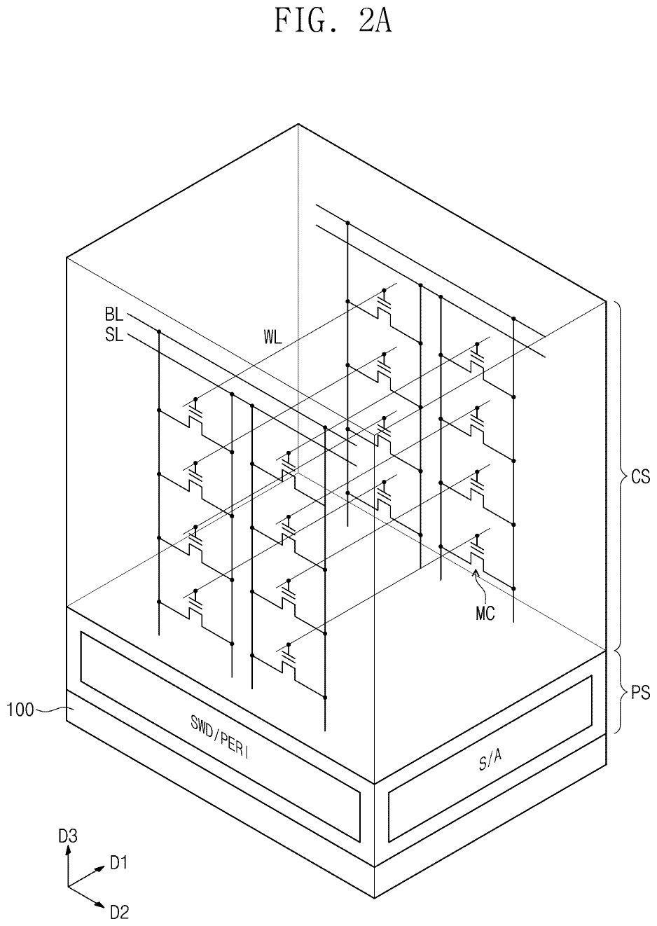

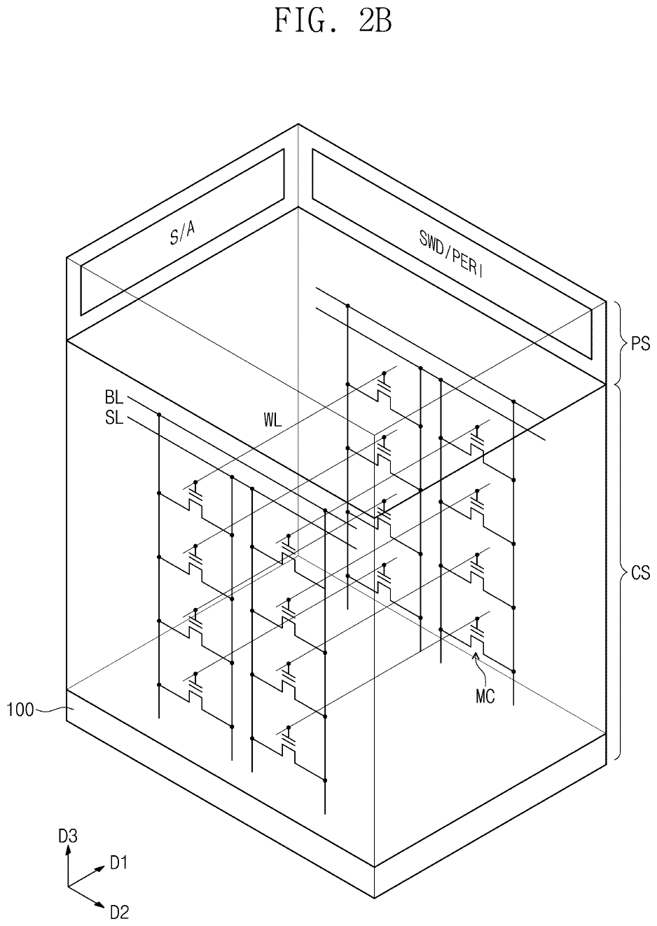

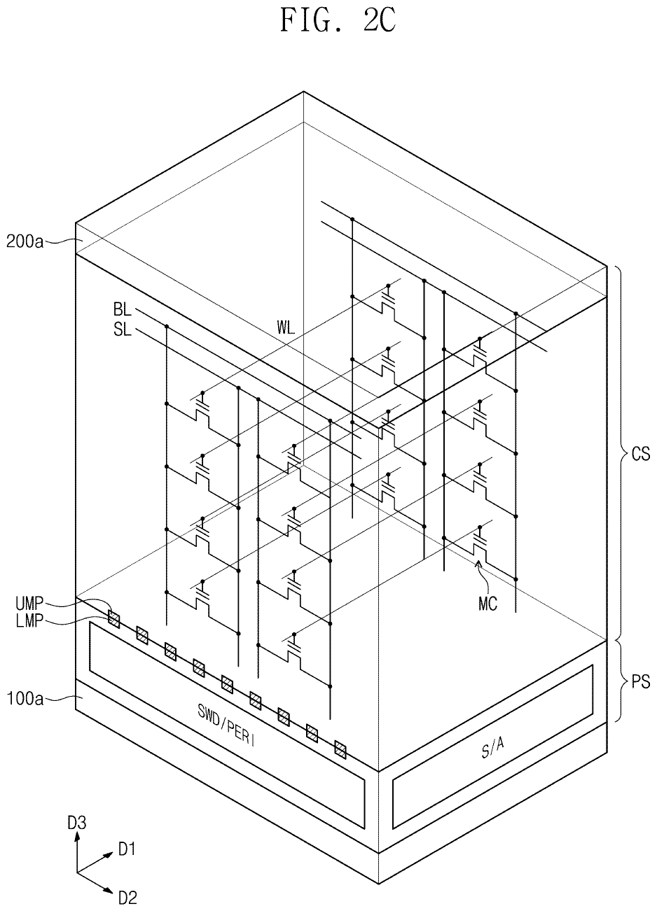

FIGS. 2A, 2B and 2C are schematic perspective views of the three-dimensional semiconductor device according to some embodiments of the inventive concept.

Referring to FIG. 2A, the three-dimensional semiconductor device may include a substrate 100, a peripheral circuit structure PS on the substrate 100 and a cell array structure CS on the peripheral circuit structure PS.

The peripheral circuit structure PS may include core and peripheral circuits formed on the substrate 100. The core and peripheral circuits may include the row and column decoders 2 and 4 (see FIG. 1), the sense amplifier 3 (see FIG. 1) and the control logic 5 (see FIG. 1) described with reference to FIG. 1.

The substrate 100 may have a shape of a plate expanding along a plane defined by a first direction D1 and a second direction D2. The first direction D1 and the second direction D2 may be parallel to an upper surface of the substrate 100 and may intersect (cross) each other. For example, the first direction D1 and the second direction D2 may be horizontal directions perpendicular to each other. The peripheral circuit structure PS and the cell array structure CS may be sequentially stacked on the substrate 100 in a third direction D3 perpendicular (vertical) to the upper surface of the substrate 100.

The cell array structure CS may include the bit lines BL, the source lines SL, the word lines WL and the memory cells MC therebetween. Each of the memory cells MC may be (electrically) connected to one word line WL, one bit line BL and one source line SL.

Referring to FIG. 2B, the semiconductor device may include the cell array structure CS on the substrate 100, and the peripheral circuit structure PS on the cell array structure CS. The cell array structure CS may be disposed between the substrate 100 and the peripheral circuit structure PS. The peripheral circuit structure PS may include core and peripheral circuits.

Referring to FIG. 2C, the semiconductor device may have a chip-to-chip (C2C) structure. The peripheral circuit structure PS may include a first substrate 100a. Lower metal pads LMP may be provided on an uppermost portion (an upper surface) of the peripheral circuit structure PS. The lower metal pads LMP may be electrically connected to the core and peripheral circuits. The lower metal pads LMP may be bonded to upper metal pads UMP of the cell array structure CS.

The cell array structure CS may include a second substrate 200a, and the upper metal pads UMP may be provided on a lowermost portion (a lower surface) of the cell array structure CS. The upper metal pads UMP may be electrically connected to the bit lines BL, the source lines SL and the word lines WL. The upper metal pads UMP may be electrically connected to the memory cells MC.

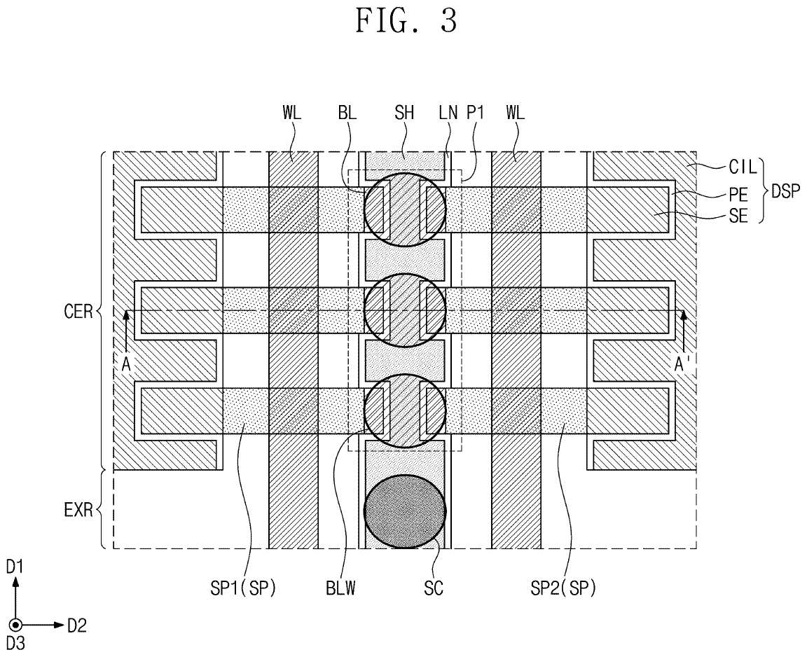

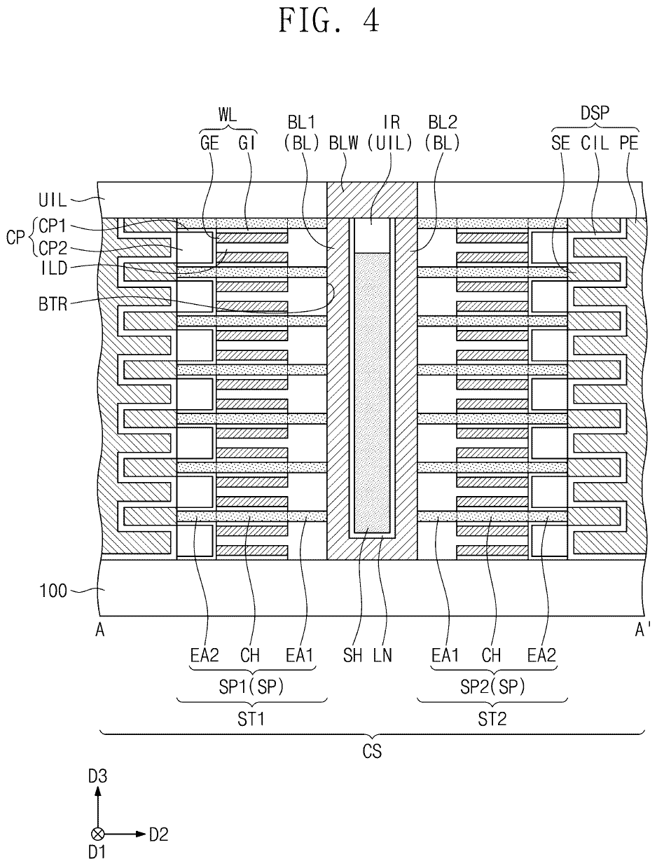

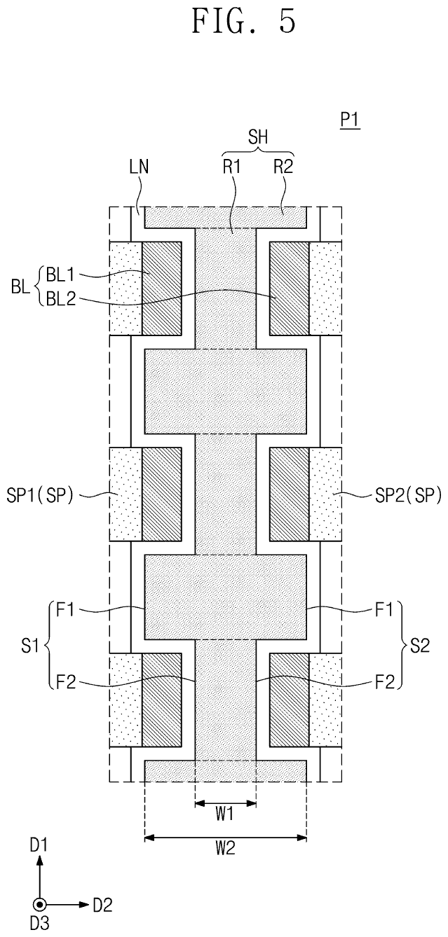

FIG. 3 is a plan view of the three-dimensional semiconductor device according to some embodiments of the inventive concept. FIG. 4 is a cross-sectional view corresponding to line A-A′ of FIG. 3. FIG. 5 is an enlarged diagram corresponding to PI of FIG. 3.

Referring to FIGS. 3 and 4, the three-dimensional semiconductor device may include the substrate 100 including a cell array region CER and an extension region EXR. For example, the substrate 100 may be a semiconductor substrate, an insulating substrate, a silicon-on-insulator (SOI) substrate or a germanium-on-insulator (GOI) substrate. For example, the semiconductor substrate may be a silicon substrate, a germanium substrate or a silicon-germanium substrate. The substrate 100 may have a shape of a plate expanding along a plane defined by the first direction D1 and the second direction D2. The first direction D1 and the second direction D2 may be directions parallel to the upper surface of the substrate 100, and may intersect (cross) each other. For example, the substrate 100 may include the peripheral circuit structure PS described with reference to FIGS. 2A and 2C.

The cell array structure CS may be provided on the cell array region CER of the substrate 100. Although only one cell array structure CS is shown on the substrate 100 in the diagram, but an embodiment of the inventive concept is not limited thereto. For example, the cell array structure CS may include a plurality of cell array structures CS next to each other in the second direction D2. Hereinafter, for convenience of description, a single cell array structure CS will be described, but the description below may be identically applied to another cell array structure CS.

The cell array structure CS may include a first stack structure ST1 and a second stack structure ST2 next to each other in the second direction D2. Each of the first stack structure ST1 and the second stack structure ST2 may include semiconductor patterns SP, word lines WL, and peripheral components extending around (e.g., surrounding) the semiconductor patterns SP and the word lines WL. Each of the semiconductor patterns SP, the word lines WL, and the peripheral components will be specifically described below.

The semiconductor pattern SP may be spaced apart from the substrate 100 in the third direction D3. In other words, the semiconductor pattern SP may be floated above (spaced apart from) the substrate 100. The semiconductor pattern SP may extend on the substrate 100 in the second direction D2. For example, the semiconductor pattern SP may have a shape of a bar extending in the second direction D2.

The semiconductor pattern SP may include a first edge portion EA1 and a second edge portion EA2 spaced apart from each other in the second direction D2, and a channel region CH therebetween. The channel region CH of the semiconductor pattern SP may vertically overlap (e.g., overlap in the third direction D3 with) the word line WL to be described later. The first edge portion EA1 of the semiconductor pattern SP may be (electrically) connected to a bit line BL to be described later. The second edge portion EA2 may be (electrically) connected to a data storage pattern DSP to be described later. In the present specification, the wording, ‘A and B are connected to each other’ may include not only that A and B are in direct contact with each other to be connected to each other, but also that A and B are indirectly connected to each other through C (for example, a component having conductivity) between A and B. Here, component C may be a single component or a plurality of components.

The semiconductor pattern SP may include, for example, single-crystalline semiconductor, polycrystalline semiconductor, oxide semiconductor and/or a two-dimensional material. For example, the single-crystalline semiconductor may include (e.g., may be) single-crystalline silicon. For example, the polycrystalline semiconductor may include (e.g., may be) polysilicon. For example, the oxide semiconductor may include (e.g., may be) indium-gallium-zinc oxide (IGZO). For example, the two-dimensional material may include (e.g., may be) MoS₂, WS₂, MoSe₂ and/or WSe₂. In the present specification, each of wordings such as “A or B”, “at least one of A and B”, “at least one of A or B”, “A, B or C”, “at least one of A, B and C”, and “at least one of A, B or C” may include any one of items listed together with the corresponding wording thereamong, or all possible combinations thereamong. As used herein, the term “and/or” includes any and all combinations of one or more of the associated listed items.

For example, each of the first and second edge portions EA1 and EA2 of the semiconductor pattern SP may include an impurity region doped with an impurity (for example, an N-type or P-type impurity) thereinside. The impurity region may constitute a source/drain region of a transistor.

The semiconductor pattern SP may be provided in plurality. The semiconductor patterns SP may be disposed spaced apart from each other along the first direction D1 and the third direction D3. For example, upper surfaces of the semiconductor patterns SP disposed along (arranged in) the first direction D1 may be aligned (coplanar) with each other. The semiconductor patterns SP disposed along (arranged in) the third direction D3 may vertically overlap (e.g., overlap in the third direction D3 with) each other. For example, sidewalls of the semiconductor patterns SP disposed along (arranged in) the third direction D3 may be aligned with each other (in the third direction D3).

The semiconductor pattern SP may include first semiconductor patterns SP1 provided in the first stack structure ST1 and second semiconductor patterns SP2 provided in the second stack structure ST2. The first semiconductor patterns SP1 may be disposed spaced apart from each other (may be arranged) in the first direction D1 and the third direction D3. The second semiconductor patterns SP2 may be disposed spaced apart from each other (may be arranged) in the first direction D1 and the third direction D3. The first semiconductor patterns SP1 may be disposed spaced apart from second semiconductor patterns SP2 in the second direction D2. The first edge portions EA1 of the first semiconductor patterns SP1 may be more adjacent (e.g., closer) to the first edge portions EA1 of the second semiconductor patterns SP2 than the second edge portions EA2 of the second semiconductor patterns SP2. For example, the first edge portions EA1 of the first semiconductor patterns SP1 may face the corresponding first edge portions EA1 of the second semiconductor patterns SP2, respectively.

The word line WL may extend around (e.g., surround) the channel regions CH of the semiconductor patterns SP disposed spaced apart from each other in the first direction D1, and may extend along the first direction D1. The word line WL may be provided in plurality. The word lines WL may be disposed spaced apart from each other in the third direction D3. Some of the word lines WL may extend from the cell array region CER to the extension region EXR. In some embodiments, the word lines WL may be in the cell array region CER and the extension region EXR. For example, the word lines WL extending to the extension region EXR may have a step structure on a cross-sectional view. In some embodiments, widths (widths in the second direction D2) of the word lines WL extending to the extension region EXR (in the first direction D1) may be substantially the same as each other.

The word line WL may include a gate dielectric layer GI extending around (e.g., surrounding) the channel region CH of the semiconductor pattern SP, and a gate pattern GE extending on the gate dielectric layer GI in (along) the first direction D1. For example, the gate dielectric layer GI may include one single layer, such as a high-dielectric layer, a silicon oxide layer, a silicon nitride layer, a silicon oxynitride layer, and/or a combination thereof. In the present specification, a high-k material is defined as a material having a higher dielectric constant than silicon oxide.

For example, the gate pattern GE may include Ti, TiN, TiSiN, TION, W, WN, Mo, MoN, MoOₓN_{y}, Ta, TaN, Poly Si, Li, Na, K, Cs, Rb, Sr, Ba, Ca, Ce, Sm, Eu, Mg, Sc, Y, Hf, Tl, As, La, Nd, Gd, Tb, Lu, Th, U, Mn, Al, Ga, In, Pb, Cd, Bi and/or Zr. For example, the gate pattern GE may be a single layer or a composite layer.

The bit line BL may be interposed between the first semiconductor patterns SP1 and the second semiconductor patterns SP2 (in the second direction D2). A bit line trench BTR may be defined between the first stack structure ST1 and the second stack structure ST2 (in the second direction D2). The bit line BL may be on (e.g., may (conformally) cover or overlap) an inner surface of the bit line trench BTR. The bit line BL may be a single layer including one material or a composite layer including at least two materials. For example, the bit line BL may include a metal material (e.g., Ti, Mo, W, Cu, Al, Ta, Ru, Ir, Co, or the like), metal nitride (e.g., nitride of Ti, Mo, W, Cu, Al, Ta, Ru, Ir, Co, or the like), and/or metal silicide (e.g., silicide of Ti, Mo, W, Cu, Al, Ta, Ru, Ir, Co, or the like).

The bit line BL may include a first bit line BL1 extending in (along) the third direction D3 on side surfaces of the first edge portions EA1 of the first semiconductor patterns SP1 disposed spaced apart from each other in (along) the third direction D3. The first bit line BL1 may be (electrically) connected to the first edge portions EA1 of the first semiconductor patterns SP1. The bit line BL may further include a second bit line BL2 extending in (along) the third direction D3 on the side surfaces of the first edge portions EA1 of the second semiconductor patterns SP2 disposed spaced apart from each other in (along) the third direction D3. The second bit line BL2 may be (electrically) connected to the first edge portions EA1 of the second semiconductor patterns SP2.

For example, on a cross-sectional view, the bit line BL may have a U-type profile. In this case, vertical portions of the bit line BL extending in (along) the third direction D3 may correspond to the first bit line BL1 and the second bit line BL2, and the first bit line BL1 and the second bit line BL2 may be connected to each other through a horizontal portion (a lower portion) of the bit line BL.

The first bit line BL1 may include first bit lines BL1 disposed spaced apart from each other in (along) the first direction D1. The second bit line BL2 may include second bit lines BL2 disposed spaced apart from each other in (along) the first direction D1. The first bit lines BL1 may be disposed spaced apart from the (corresponding) second bit lines BL2 in the second direction D2.

The data storage pattern DSP may extend along the third direction D3 on side surfaces of the second edge portions EA2 of the semiconductor patterns SP disposed spaced apart from each other in (along) the third direction D3. The data storage pattern DSP may be (electrically) connected to the second edge portions EA2 of the semiconductor patterns SP.

The data storage pattern DSP may include a storage electrode SE, a plate electrode PE and a dielectric layer CIL therebetween. For example, the three-dimensional semiconductor device may be a dynamic random access memory (DRAM), and in this case, the data storage pattern DSP may be utilized as a capacitor. The storage electrode SE may be spaced apart from the plate electrode PE by the dielectric layer CIL.

Each of the storage electrode SE and the plate electrode PE may include a conductive material. For example, each of the storage electrode SE and the plate electrode PE may include impurity-doped silicon (Si), impurity-doped silicon germanium (SiGe), a metal material (e.g., Ti, Mo, W, Cu, Al, Ta, Ru, Ir, Co, Pt, Au, Ag, or the like), metal nitride (e.g., nitride of Ti, Mo, W, Cu, Al, Ta, Ru, Ir, Co, Pt, Au, Ag, or the like, titanium silicon nitride (e.g., TiSiN), titanium aluminum nitride (e.g., TiAlN), and/or tantalum aluminum nitride (e.g., TaAlN or the like)), conducting oxide (e.g., PtO, RuO₂, IrO₂, SRO (SrRuO₃), BSRO ((Ba,Sr)RuO₃), CRO (CaRuO₃), and/or LSCo), and/or metal silicide. Each of the storage electrode SE and the plate electrode PE may be a single layer composed of a single material or a composite layer including at least two materials.

For example, the dielectric layer CIL may include metal oxide such as HfO₂, ZrO₂, Al₂O₃, La₂O₃, Ta₂O₃, and/or TiO₂, and/or a dielectric material, having a perovskite structure, such as SrTiO₃ (STO), (Ba,Sr)TiO₃ (BST), BaTiO₃, PZT, and/or PLZT.

In some embodiments, the data storage pattern DSP may be a variable resistance pattern capable of being switched to two resistance states by an electrical pulse. In this case, the data storage pattern DSP may include a phase-change material changing a crystalline state according to an amount of current, a perovskite compound, transition metal oxide, a magnetic material, a ferromagnetic material and/or an anti-ferromagnetic material.

Although not shown, a silicide pattern may be provided between the storage electrode SE and the semiconductor pattern SP. The silicide pattern may include metal silicide (for example, silicide of Ti, Mo, W, Cu, Al, Ta, Ru, Ir, Co or the like). The storage electrode SE may be provided in plurality, and the storage electrodes SE may be next to (adjacent) each other in the third direction D3.

The plate electrode PE may include a first region extending in (along) the third direction D3, and a second region protruding from the first region in the second direction D2. The second region of the plate electrode PE may be interposed between the (adjacent) storage electrodes SE disposed in (along) the third direction D3. For example, the second regions of the plate electrode PE and the storage electrodes SE may overlap and may be alternately arranged in the third direction D3.

A capping pattern CP including an insulating material may be interposed between the word line WL and the data storage pattern DSP (in the second direction D2), and may space the same apart from each other (in the second direction D2). The capping pattern CP may include a first capping pattern CP1 between the word line WL and the data storage pattern DSP, and a second capping pattern CP2 between the first capping pattern CP1 and the data storage pattern DSP.

An interlayered insulating layer ILD including an insulating material may be interposed between the word lines WL disposed spaced apart from each other in the third direction D3, and may space the same apart from each other. The interlayered insulating layer ILD may be interposed between the bit line BL and the word line WL (in the second direction D2), and may space the same apart from each other (in the second direction D2). The interlayered insulating layer ILD may be interposed between the semiconductor patterns SP disposed spaced apart from each other in the third direction D3.

A shielding pattern SH may be interposed between the first bit lines BL1 and the second bit lines BL2 (in the second direction D2). The shielding pattern SH may extend in (along) the first direction D1 and the third direction D3 between the first bit lines BL1 and the second bit lines BL2 (in the second direction D2). The shielding pattern SH may extend from the cell array region CER to the extension region EXR in (along) the first direction D1. For example, in a plan view, the shielding pattern SH may extend between the cell array region CER and the extension region EXR in the first direction Dland may overlap the cell array region CER and the extension region EXR in the second direction D2. The shielding pattern SH may include a conductive material. For example, the shielding pattern SH may include a metal material and/or doped polysilicon.

The shielding pattern SH may include first regions R1 between the first bit lines BL1 and the second bit lines BL2 (in the second direction D2), and second regions R2 interposed between the first regions R1 (in the first direction D1). The first regions R1 and the second regions R2 of the shielding pattern SH may be alternately disposed in (along) the first direction D1.

For example, the shielding pattern SH may have a fish-bone shape in a plan view, and the shape will be specifically described below with reference to FIG. 5.

Referring to FIG. 5, with respect to the second direction D2, a width W2 of each of the second regions R2 of the shielding pattern SH (in the second direction D2) may be greater than a width W1 of each of the first regions R1 of the shielding pattern SH (in the second direction D2). The shielding pattern SH may have a first side surface S1 and a second side surface S2 each extending with a wavy profile in (along) the first direction D1. Herein, when an element is described to have a “wavy profile in the first direction D1”, such description may mean that the element has different widths in the second direction D2 that intersects the first direction D1 so that a side surface profile of the element protrudes and recessed in the second direction D2 while the side surface extends in the first direction D1 as a whole. The first side surface S1 and the second side surface S2 of the shielding pattern SH may be opposed to each other (in the second direction D2). First surfaces F1 of the first side surface S1 of the shielding pattern SH (e.g., the second regions R2 of the shielding pattern SH) may protrude in the second direction D2 more than second surfaces F2 of the first side surface S1 of the shielding pattern SH (e.g., the first regions R1 of the shielding pattern SH). First surfaces F1 of the second side surface S2 of the shielding pattern SH (e.g., the second regions R2 of the shielding pattern SH) may protrude in the second direction D2 more than second surfaces F2 of the second side surface S2 of the shielding pattern SH (e.g., the first regions R1 of the shielding pattern SH). For example, (each of) the first surfaces F1 of the first side surface S1 of the shielding pattern SH (e.g., the second regions R2 of the shielding pattern SH) may farther than (each of) the second surfaces F2 of the first side surface S1 of the shielding pattern SH (e.g., the first regions R1 of the shielding pattern SH) in the second direction D2 from the corresponding closest central portion of the shielding pattern SH in the second direction D2. For example, (each of) the first surfaces F1 of the second side surface S2 of the shielding pattern SH (e.g., the second regions R2 of the shielding pattern SH) may farther than (each of) the second surfaces F2 of the second side surface S2 of the shielding pattern SH (e.g., the first regions R1 of the shielding pattern SH) in the second direction D2 from the corresponding closest central portion of the shielding pattern SH in the second direction D2. Accordingly, the second regions R2 of the shielding pattern SH may protrude in the second direction D2 more than the first regions R1 of the shielding pattern SH.

The first regions R1 of the shielding pattern SH may be interposed between the first bit lines BL1 and the (corresponding) second bit lines BL2 (in the second direction D2), and may space the same apart from each other (in the second direction D2). The second regions R2 of the shielding pattern SH may be inserted between the first bit lines BL1 (in the first direction D1). The second regions R2 of the shielding pattern SH may be interposed between the first bit lines BL1 (in the first direction D1), and may space the same apart from each other (in the first direction D1). The second regions R2 of the shielding pattern SH may be inserted between the second bit lines BL2 (in the first direction D1). The second regions R2 of the shielding pattern SH may be interposed between the second bit lines BL2 (in the first direction D1), and may space the same apart from each other (in the first direction D1).

Referring to FIGS. 3, 4 and 5, a liner pattern LN may be interposed between the shielding pattern SH and the bit line BL. The liner pattern LN may include an insulating material. The liner pattern LN may be interposed between the shielding pattern SH and the first bit lines BL1, and may space the same apart from each other. The liner pattern LN may be interposed between the shielding pattern SH and the second bit lines BL2, and may space the same apart from each other. In a plan view, the liner pattern LN may extend with a wavy profile in (along) the first direction D1.

A bit line wire BLW may be provided on an upper surface of each of the first bit line BL1 and the second bit line BL2. The bit line wire BLW may be (electrically) connected to the first bit line BL1 and the second bit line BL2. A voltage provided to the bit line wire BLW may be transferred to the first bit line BL1 and the second bit line BL2 through the bit line wire BLW. The bit line wire BLW may include a conductive material.

The bit line wire BLW may include a plurality of bit line wires BLW disposed spaced apart from each other in (along) the first direction D1. The bit line wires BLW may be located at a higher level than an upper surface of the shielding pattern SH. The bit line wires BLW may be spaced apart from the shielding pattern SH by an insertion portion IR of an upper insulating layer UIL to be described later. Herein, the term “level”, “vertical level”, “height”, or the like may refer to a relative location with respect to a reference element in the third direction D3. A level, a vertical level, height, or the like may be a distance from the upper surface of the substrate 100 in the third direction D3. For example, a higher level may mean a farther distance from the upper surface of the substrate 100 in the third direction D3, and a lower level may mean a closer distance to the upper surface of the substrate 100 in the third direction D3.

A conductive contact SC may be provided on the upper surface of the shielding pattern SH on the extension region EXR. The conductive contact SC may be (electrically) connected to the shielding pattern SH. The conductive contact SC may include a conductive material. For example, a ground voltage may be applied to the conductive contact SC. In this case, the ground voltage may be transferred to the shielding pattern SH through the conductive contact SC. The conductive contact SC may be spaced apart from the bit line wires BLW in the first direction D1.

According to the inventive concept, the shielding pattern SH including a conductive material may be interposed between the first bit lines BL1 and the second bit lines BL2 (in the second direction D2). The shielding pattern SH including the conductive material may be inserted between the first bit lines BL1 (in the first direction D1), and between the second bit lines BL2 (in the first direction D1). The ground voltage may be transferred to the shielding pattern SH through the conductive contact SC, and thus electrical interference between the first bit lines BL1 and the second bit lines BL2 may be reduced. Likewise, electrical interference between the first bit lines BL1, and electrical interference between the second bit lines BL2 may be reduced. As a result, coupling between adjacent bit lines BL may be reduced. Accordingly, electrical characteristics and reliability of the three-dimensional semiconductor device may be improved.

The upper insulating layer UIL may be provided on an upper surface of each of the first stack structure ST1 and the second stack structure ST2. The upper insulating layer UIL may extend around (e.g., surround) and/or cover (or overlap) each of the bit line wires BLW and the conductive contact SC. The upper insulating layer UIL may include the insertion portion IR inserted between the bit line wires BLW and the shielding pattern SH.

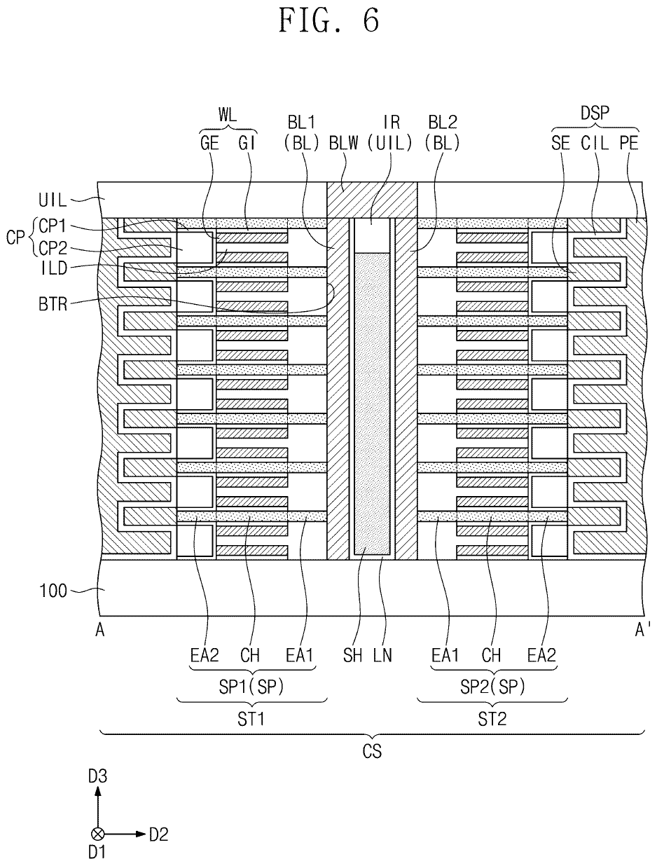

FIG. 6 is a cross-sectional view corresponding to line A-A′ of FIG. 3.

Referring to FIGS. 3 and 6, unlike what is described with reference to FIG. 4, the first bit line BL1 and the second bit line BL2 may be spaced apart from each other in the second direction D2. In other words, the horizontal portion of the bit line BL described with reference to FIG. 4 may not be provided. For example, the bit line BL may have a pillar shape. A lower surface of the liner pattern LN may be located at the (substantially) same level as a lower surface of the bit line BL. For example, the lower surface of the liner pattern LN may be coplanar with the lower surface of the bit line BL. The lower surface of the liner pattern LN may be in contact with the upper surface of the substrate 100.

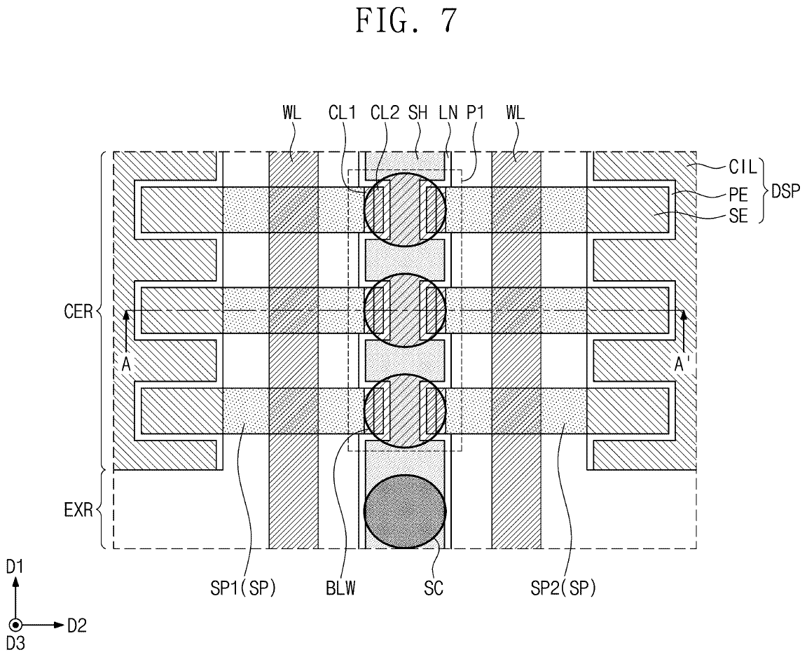

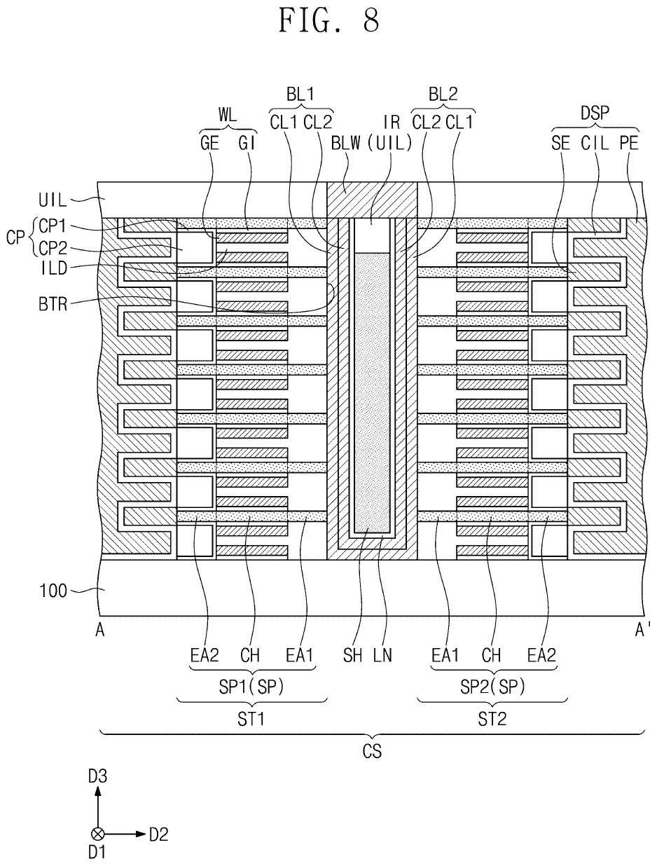

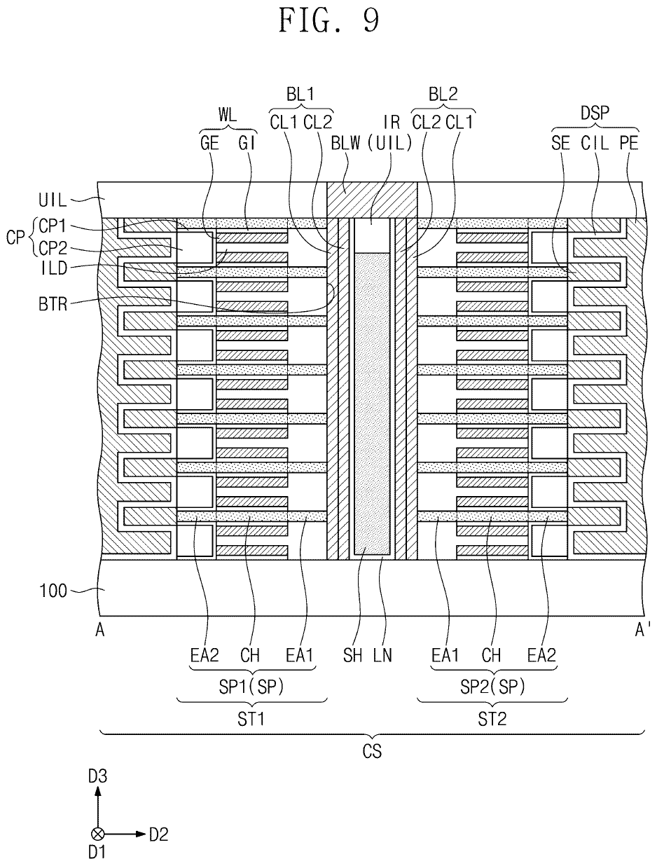

FIG. 7 is a plan view of the three-dimensional semiconductor device according to some embodiments of the inventive concept. FIG. 8 is a cross-sectional view corresponding to line A-A′ of FIG. 7. FIG. 9 is a cross-sectional view corresponding to line A-A′ of FIG. 7.

Referring to FIGS. 7, 8 and 9, a first conductive line CL1 and a second conductive line CL2 on (e.g., sequentially (conformally) covering or overlapping) an inner surface of the bit line trench BTR may be provided. The first conductive line CL1 may be more adjacent to the first edge portion EA1 of the semiconductor pattern SP than the second conductive line CL2 (in the second direction D2). For example, the first conductive line CL1 may include doped polysilicon, and the second conductive line CL2 may include a metal material. In this case, although not shown in the drawing, metal silicide may be interposed between the first conductive line CL1 and the second conductive line CL2.

The first conductive line CL1 and the second conductive line CL2 may constitute the bit line BL described with reference to FIGS. 3 and 4. As described with reference to FIGS. 3 and 4, the bit line BL adjacent to the first edge portion EA1 of the first semiconductor pattern SP1 (in other words, the first conductive line CL1 and the second conductive line CL2 adjacent to the first edge portion EA1 of the first semiconductor pattern SP1) is referred to as the first bit line BL1. Likewise, the bit line BL adjacent to the first edge portion EA1 of the second semiconductor pattern SP2 (in other words, the first conductive line CL1 and the second conductive line CL2 adjacent to the first edge portion EA1 of the second semiconductor pattern SP2) is referred to as the second bit line BL2.

Referring to FIG. 8, as described with reference to FIG. 4, the first bit line BL1 and the second bit line BL2 may be continuously connected to each other. Referring to FIG. 9, as described with reference to FIG. 6, the first bit line BL1 and the second bit line BL2 may be disposed spaced apart from each other in the second direction D2.

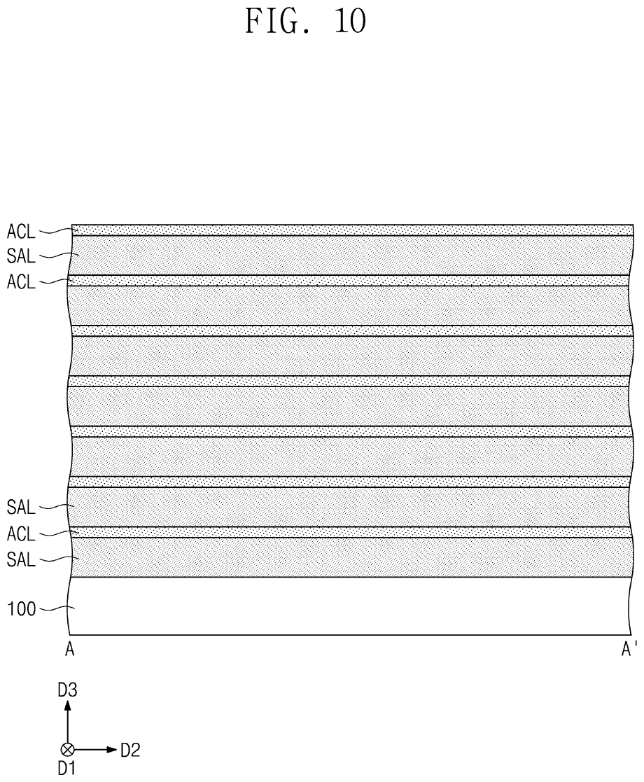

Hereinafter, referring to FIGS. 10 to 18, a method for manufacturing a three-dimensional semiconductor device according to some embodiments of the inventive concept will be described. In order to simplify description, duplicate description of that made above may be omitted, and a difference from that made above will be mainly described.

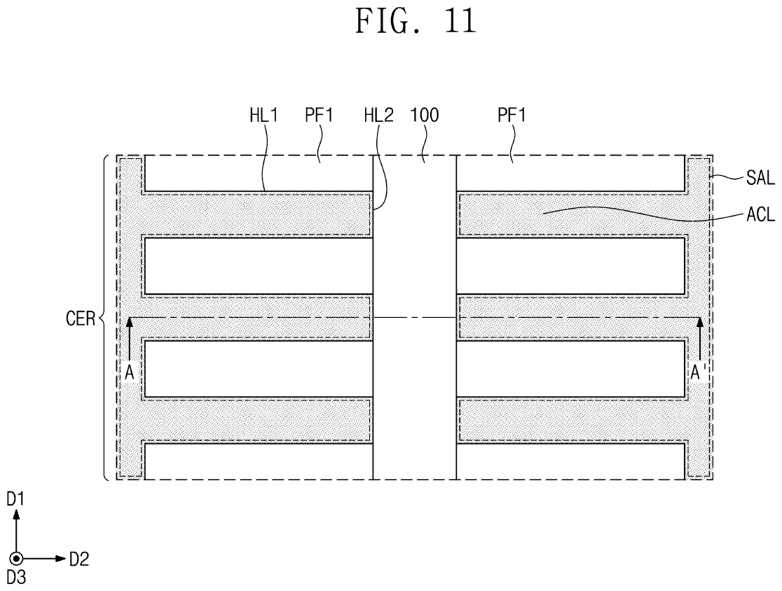

FIGS. 10 to 18 are diagrams illustrating the method for manufacturing a three-dimensional semiconductor device according to some embodiments of the inventive concept. Specifically, FIGS. 11, 13, 15 and 17 are plan views illustrating the three-dimensional semiconductor device according to some embodiments of the inventive concept. FIGS. 10, 12, 14, 16 and 18 are cross-sectional views corresponding to line A-A′ of each of FIGS. 3, 11, 13, 15 and 17.

Referring to FIGS. 3 and 10, the substrate 100 may be prepared. Sacrificial layers SAL and active layers ACL may be alternately stacked on the substrate 100 to be formed. Each of the sacrificial layers SAL and the active layers ACL may include a semiconductor material. The sacrificial layers SAL may include a material having etching selectivity with respect to the active layers ACL. Accordingly, during a process, of removing the sacrificial layers SAL, to be described later, although the sacrificial layers SAL are removed, the active layers ACL may not be removed, or may be removed less than the sacrificial layers SAL. For example, the active layers ACL may include silicon (Si), germanium (Ge) and/or silicon-germanium (SiGe), and the sacrificial layers SAL may include silicon (Si), germanium (Ge) and/or silicon-germanium (SiGe). For example, the active layers ACL may include silicon (Si), and the sacrificial layers SAL may include silicon-germanium (SiGe). For example, with respect to the third direction D3, the sacrificial layers SAL may have a greater thickness than the active layers ACL, but an embodiment of the inventive concept is not limited thereto.

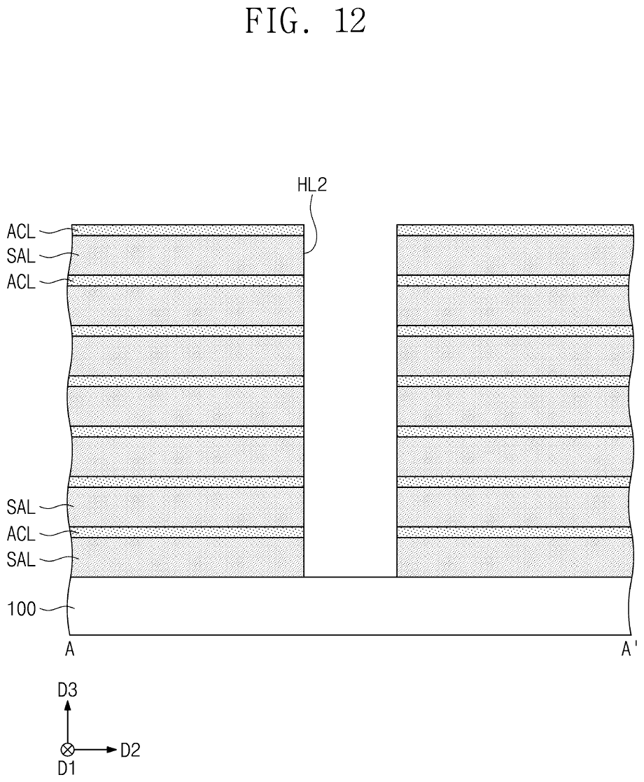

Referring to FIGS. 11 and 12, first holes HL1 may be formed on the substrate 100 by partially removing each of the sacrificial layers SAL and the active layers ACL. The first holes HL1 may be formed so as to be next to (to be spaced apart from) each other in the first direction D1 and the second direction D2. The upper surface of the substrate 100 may be partially exposed to the outside by the first holes HL1. The sacrificial layers SAL and the active layers ACL may be formed so as to include regions extending long in the first direction D1, and regions extending long in the second direction D2 through the removing process.

First preliminary filling patterns PF1 may be on (e.g., may cover or overlap) the exposed portion of the upper surface of the substrate 100, and may be formed so as to (at least partially) fill the insides of the first holes HL1. For example, the first preliminary filling patterns PF1 may include an insulating material. The first preliminary filling patterns PF1 may be formed so as to be next to (to be spaced apart from) each other in the first direction D1 and the second direction D2.

Second holes HL2 may be formed on the substrate 100 by partially removing the regions, extending long in the first direction D1, among the sacrificial layers SAL and the active layers ACL. The second holes HL2 may be formed so as to extend in (along) the first direction D1. Both side surfaces (e.g., opposite side surface in the second direction D2) of the sacrificial layers SAL and the active layers ACL may be exposed to the outside by the second holes HL2. The upper surface of the substrate 100 may be partially exposed to the outside by the second holes HL2.

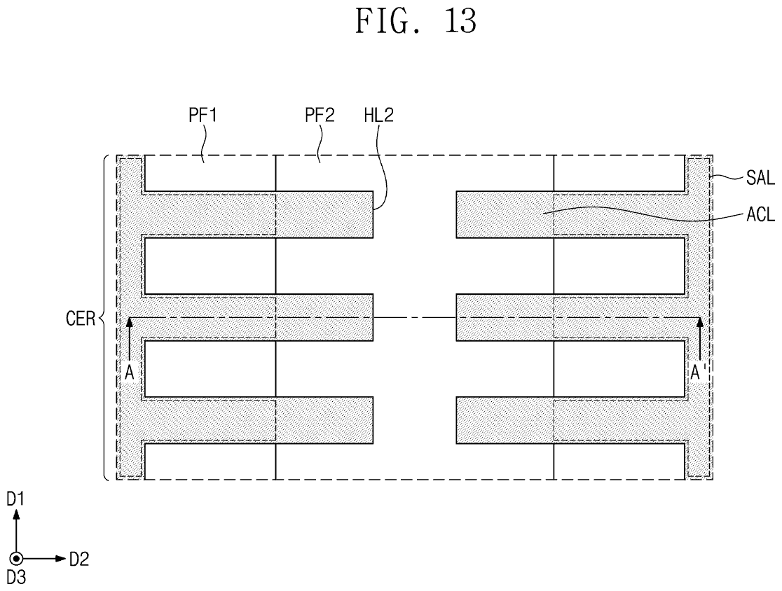

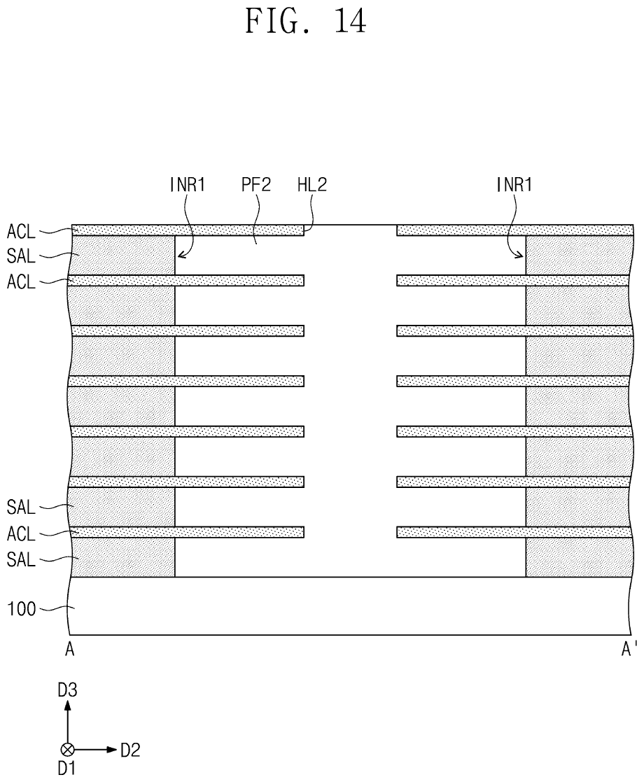

Referring to FIGS. 13 and 14, the exposed both side surfaces (e.g., opposite side surface in the second direction D2) of the sacrificial layers SAL may be selectively removed through the second holes HL2. Accordingly, first inner regions INR1 may be formed between the active layers ACL disposed in (along) the third direction D3. Each of the first preliminary filling patterns PF1 may be partially removed together during the removing process. Sidewalls of the first preliminary filling patterns PF1 may be aligned with sidewalls of the sacrificial layers SAL (in the second direction D2).

Second preliminary filling patterns PF2 may be formed so as to (at least partially) fill the first inner regions INR1, a region in which the first preliminary filling patterns PF1 are partially removed, and the insides of the second holes HL2. The second preliminary filling patterns PF2 may extend around (surround) and may be on (e.g., may cover or overlap) the active layers ACL not vertically overlapping (not overlapping in the third direction D3) the sacrificial layers SAL. For example, the second preliminary filling patterns PF2 may not overlap the sacrificial layers SAL in the third direction D3. The second preliminary filling patterns PF2 may include a single layer or composite layer including an insulating material. For example, the second preliminary filling patterns PF2 may include silicon oxide and/or silicon nitride.

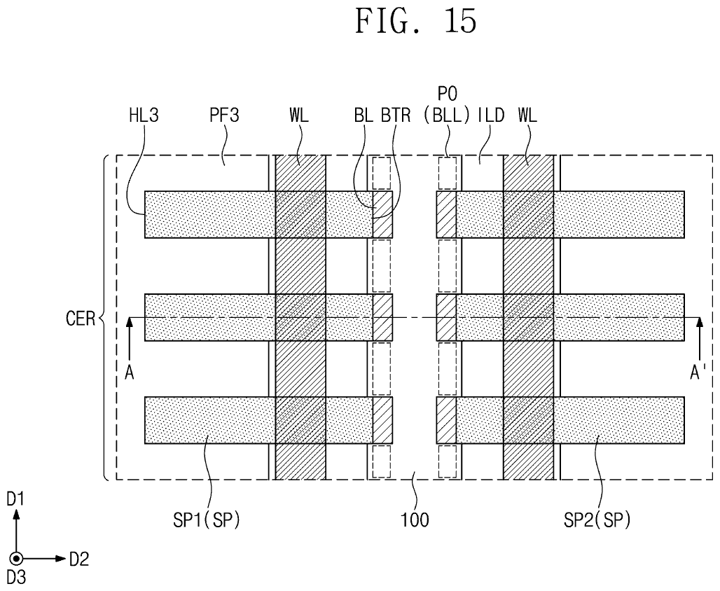

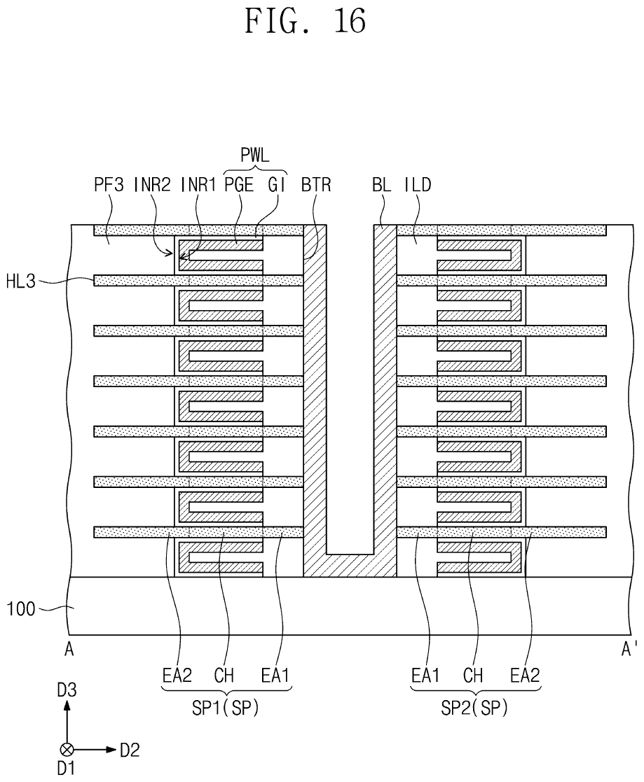

Referring to FIGS. 15 and 16, third holes HL3 (not illustrated) may be formed on the substrate 100 by removing the region, extending long in the first direction D1, among the sacrificial layers SAL and the active layers ACL. One active layer ACL may be separated into the semiconductor patterns SP next to each other in the first direction D1 during the process of forming the third holes HL3. The semiconductor pattern SP may include the first semiconductor pattern SP1 and the second semiconductor pattern SP2 next to (adjacent) each other in the second direction D2. The sacrificial layers SAL may be exposed to the outside again during the process of forming the third holes HL3.

The exposed sacrificial layers SAL may be entirely removed on the substrate 100 through the third holes HL3. Accordingly, second inner regions INR2 may be formed between some regions (portions) of the active layers ACL not overlapping the second preliminary filling patterns PF2 (in the third direction D3) (see FIG. 14). The first preliminary filling patterns PF1 (see FIG. 13) may be entirely removed on the substrate 100 during the removing process. Thereafter, third preliminary filling patterns PF3 may be formed so as to (at least partially) fill the second inner regions INR2, a region in which the first preliminary filling patterns PF1 (see FIG. 13) are removed, and the insides of the third holes HL3. The third preliminary filling patterns PF3 may include a single layer or composite layer including an insulating material. For example, the third preliminary filling patterns PF3 may include silicon oxide and/or silicon nitride.

Thereafter, the second preliminary filling pattern PF2 (see FIG. 14) may be removed on the substrate 100. Thereafter, a gate dielectric layer GI and a preliminary gate conductive layer PGE may be sequentially formed in the first inner regions INR1, and may constitute a preliminary word line PWL. The gate dielectric layer GI and the preliminary gate conductive layer PGE may be formed on (e.g., so as to partially sequentially (conformally) cover or overlap) the semiconductor pattern SP. For example, the gate dielectric layer GI and the preliminary gate conductive layer PGE may be on (may overlap in the third direction D3) the semiconductor pattern SP. The gate dielectric layer GI and the preliminary gate conductive layer PGE may be formed on (e.g., so as to partially surround and/or cover (or overlap)) the semiconductor pattern SP. One gate dielectric layer GI and one preliminary gate conductive layer PGE may be formed on (e.g., so as to partially surround and/or cover (or overlap)) the semiconductor patterns SP next to (adjacent) each other in the first direction D1 and/or the third direction D3. Thereafter, the interlayered insulating layer ILD may be formed in (a remaining region of) the first inner regions INR1 and in a region from which the second preliminary filling pattern PF2 are removed.

Thereafter, the bit line trench BTR may be formed, and a bit line layer BLL on (e.g., (conformally) covering or overlapping) an inner surface of the bit line trench BTR may be formed. Thereafter, a process of removing a portion PO of the bit line layer BLL may be performed. Accordingly, the bit line layer BLL may be separated into the bit lines BL disposed spaced apart from each other along the first direction D1.

For example, although not shown, the bit line layer BLL may be composed of a plurality of layers (for example, a composite layer including doped polysilicon and/or a metal material), not a single layer. In this case, the bit lines BL formed in a process of removing the portion PO of the bit line layer BLL may correspond to the bit line BL described with reference to FIG. 8.

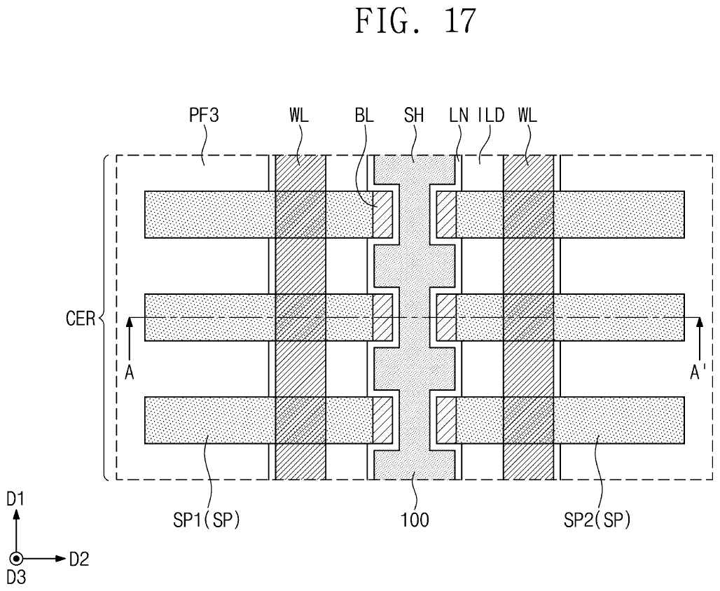

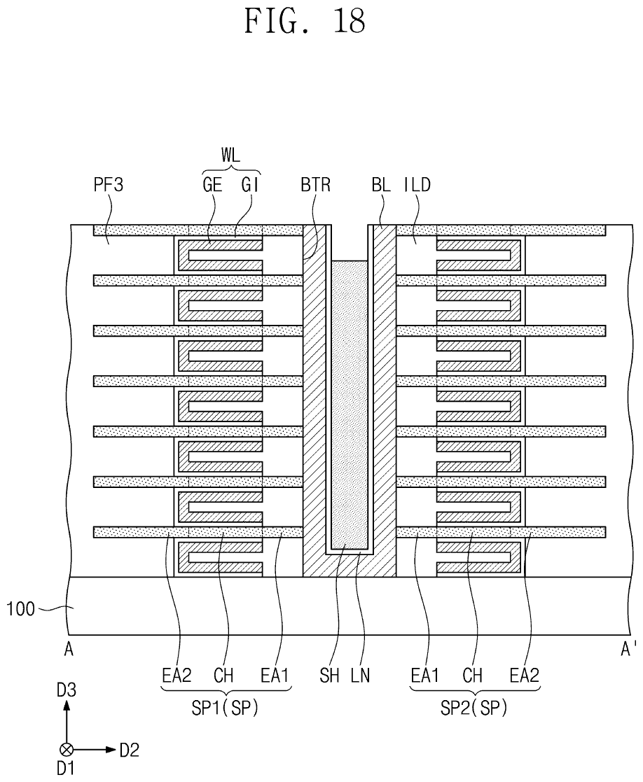

Referring to FIGS. 17 and 18, the liner pattern LN on (e.g., (conformally) covering or overlapping) a surface of the exposed bit line BL may be formed. The shielding pattern SH partially filling the bit line trench BTR may be formed.

Referring back to FIGS. 3 and 4, the third preliminary filling patterns PF3 (see FIG. 18) may be removed on the substrate 100. Each of the gate dielectric layer GI and the preliminary gate conductive layer PGE may be partially removed together during the process of removing the third preliminary filling patterns PF3 (see FIG. 18). Accordingly, one gate dielectric layer GI may be separated into a plurality of gate dielectric layers GI next to (adjacent) each other in the third direction D3. In addition, one preliminary gate conductive layer PGE may be separated into a plurality of gate electrodes GE next to (adjacent) each other in the third direction D3. The gate dielectric layer GI and the gate electrode GE may constitute the word line WL.

The first capping pattern CP1 and the second capping pattern CP2 may be formed in a region in which the third preliminary filling pattern PF3 (see FIG. 18) is removed, and may constitute the capping pattern CP. The capping pattern CP may be partially removed, and the second edge portions EA2 of the semiconductor patterns SP may be exposed to the outside.

A process of partially removing the exposed second edge portions EA2 of the semiconductor patterns SP may be performed. A process of partially removing the capping pattern CP may be also performed together during the removing process.

The storage electrodes SE may be formed on the second edge portions EA2 of the semiconductor patterns SP. For example, forming the storage electrodes SE may include forming silicide patterns (not shown) on the second edge portions EA2 of the semiconductor patterns SP, and forming the storage electrodes SE through a selective epitaxial growth (SEG) process using the silicide patterns as seeds.

The process of partially removing the capping pattern CP may be performed. Accordingly, a side surface of the capping pattern CP may be aligned with a side surface of the second edge portion EA2 of the semiconductor pattern SP. Thereafter, the dielectric layer CIL may be formed on (e.g., so as to (conformally) cover or overlap) the storage electrodes SE. The plate electrode PE may be formed so as to (at least partially) fill spaces between the storage electrodes SE. The storage electrode SE, the dielectric layer CIL and the plate electrode PE may constitute the data storage pattern DSP. Thereafter, the upper insulating layer UIL may be formed on (e.g., so as to cover or overlap) the cell array region CER and the extension region EXR of the substrate 100.

The bit line wires BLW may be formed so as to extend into (e.g., penetrate) the upper insulating layer UIL to be (electrically) connected to the bit lines BL. The conductive contact SC may be formed so as to extend into (e.g., penetrate) the upper insulating layer UIL to be (electrically) connected to the shielding pattern SH.

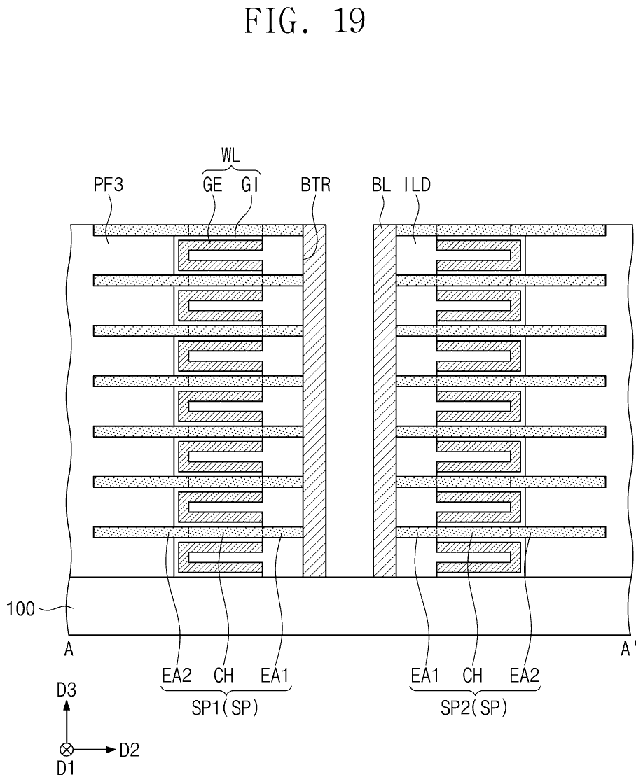

FIG. 19 is a diagram illustrating the method for manufacturing a three-dimensional semiconductor device according to some embodiments of the inventive concept. Specifically, FIG. 19 is a cross-sectional view corresponding to line A-A′ of FIG. 15.

Referring to FIGS. 15 and 19, after the process of forming the bit line BL described with reference to FIGS. 15 and 16, a process of partially removing the bit line BL may be performed in order to space the bit line BL (electrically) connected to the first semiconductor pattern SP1 and the bit line BL (electrically) connected to the second semiconductor pattern SP2 apart from each other. Accordingly, the bit line BL may be separated into the bit lines BL spaced apart from each other in the second direction D2. For example, the bit line BL may be the bit line BL described with reference to FIG. 6 or 9.

According to the inventive concept, a shielding pattern including a conductive material may be interposed between first bit lines and second bit lines. The shielding pattern including a conductive material may be inserted between the first bit lines, and between the second bit lines. A ground voltage may be transferred to the shielding pattern through a conductive contact, and thus electrical interference between the first bit lines and the second bit lines may be reduced. Likewise, electrical interference between the first bit lines and electrical interference between the second bit lines may be reduced. As a result, coupling between adjacent bit lines may be reduced. Accordingly, electrical characteristics and reliability of a three-dimensional semiconductor device may be improved.

The above description of embodiments of the inventive concept provides an example for description of the inventive concept. Therefore, the inventive concept is not limited to the above embodiments, and it is obvious that various modifications and changes such as combining the above embodiments may be made by those skilled in the art within the technical scope of the inventive concept.

What is claimed is:

1. A three-dimensional semiconductor device comprising:
a substrate;
first semiconductor patterns on the substrate, wherein the first semiconductor patterns are spaced apart from each other in a first direction that is parallel to an upper surface of the substrate;
second semiconductor patterns on the substrate, wherein the second semiconductor patterns are spaced apart from the first semiconductor patterns in a second direction that is parallel to the upper surface of the substrate and intersects the first direction, and wherein the second semiconductor patterns are spaced apart from each other in the first direction;
first bit lines on edge portions of the first semiconductor patterns;
second bit lines on edge portions of the second semiconductor patterns, wherein the edge portions of the second semiconductor patterns face the edge portions of the first semiconductor patterns in the second direction; and
a shielding pattern between the first bit lines and the second bit lines in the second direction,
wherein the shielding pattern includes first regions and second regions,
wherein the first regions of the shielding pattern are between the first bit lines and the second bit lines in the second direction,
wherein at least one of the second regions of the shielding pattern is between respective adjacent ones of the first regions of the shielding pattern in the first direction, and
wherein a width of the at least one of the second regions of the shielding pattern in the second direction is greater than a width of at least one of the first regions of the shielding pattern in the second direction.

2. The three-dimensional semiconductor device of claim 1, wherein the at least one of the second regions of the shielding pattern is between respective adjacent ones of the first bit lines in the first direction.

3. The three-dimensional semiconductor device of claim 1, wherein the at least one of the second regions of the shielding pattern is between respective adjacent ones of the second bit lines in the first direction.

4. The three-dimensional semiconductor device of claim 1, wherein opposite side surfaces of the shielding pattern in the second direction have wavy profiles in the first direction.

5. The three-dimensional semiconductor device of claim 1, wherein opposite side surfaces of the at least one of the second regions of the shielding pattern in the second direction are farther than opposite side surfaces of the at least one of the first regions of the shielding pattern in the second direction, respectively, from corresponding central regions of the shielding pattern in the second direction.

6. The three-dimensional semiconductor device of claim 1, wherein the first regions of the shielding pattern and the second regions of the shielding pattern are alternately arranged in the first direction.

7. The three-dimensional semiconductor device of claim 1, wherein the shielding pattern includes a conductive material.

8. The three-dimensional semiconductor device of claim 1, wherein each of the first bit lines is between respective adjacent ones of the second regions of the shielding pattern in the first direction.

9. The three-dimensional semiconductor device of claim 1, further comprising bit line wires on an upper surface of each of the first bit lines and the second bit lines,
wherein the bit line wires are electrically connected to the first bit lines and the second bit lines, and
wherein the shielding pattern is spaced apart from the bit line wires.

10. The three-dimensional semiconductor device of claim 1, further comprising a conductive contact on an upper surface of the shielding pattern,
wherein the conductive contact is electrically connected to the shielding pattern.

11. The three-dimensional semiconductor device of claim 1, further comprising a liner pattern between the shielding pattern and the first bit lines,
wherein the liner pattern includes an insulating material.

12. The three-dimensional semiconductor device of claim 11, wherein the liner pattern has a wavy profile in the first direction.

13. A three-dimensional semiconductor device comprising:
a substrate;
first semiconductor patterns on the substrate, wherein the first semiconductor patterns are spaced apart from each other in a first direction that is parallel to an upper surface of the substrate;
second semiconductor patterns on the substrate, wherein the second semiconductor patterns are spaced apart from the first semiconductor patterns in a second direction that is parallel to the upper surface of the substrate and intersects the first direction, and wherein the second semiconductor patterns are spaced apart from each other in the first direction;
first bit lines on edge portions of the first semiconductor patterns;
second bit lines on edge portions of the second semiconductor patterns, wherein the edge portions of the second semiconductor patterns face the edge portions of the first semiconductor patterns in the second direction; and
a shielding pattern between the first bit lines and the second bit lines in the second direction,
wherein the shielding pattern includes first regions and second regions,
wherein the first regions of the shielding pattern are between the first bit lines and the second bit lines in the second direction,
wherein at least one of the second regions of the shielding pattern is between respective adjacent ones of the first regions of the shielding pattern in the first direction, and
wherein the at least one of the second regions of the shielding pattern is between respective adjacent ones of the first bit lines in the first direction.

14. The three-dimensional semiconductor device of claim 13, wherein the at least one of the second regions of the shielding pattern is between respective adjacent ones the second bit lines in the first direction.

15. The three-dimensional semiconductor device of claim 13, wherein opposite side surfaces of the at least one of the second regions of the shielding pattern in the second direction are farther than opposite side surfaces of at least one of the first regions of the shielding pattern in the second direction, respectively, from corresponding central regions of the shielding pattern in the second direction.

16. The three-dimensional semiconductor device of claim 13, wherein opposite side surfaces of the shielding pattern in the second direction have wavy profiles in the first direction.

17. The three-dimensional semiconductor device of claim 13, wherein each of the first bit lines is between respective adjacent ones of the second regions of the shielding pattern in the first direction.

18. The three-dimensional semiconductor device of claim 13, further comprising:
bit line wires on an upper surface of each of the first bit lines and the second bit lines, wherein the bit line wires are electrically connected to the first bit lines and the second bit lines; and
an upper insulating layer between the bit line wires and the shielding pattern.

19. The three-dimensional semiconductor device of claim 13, further comprising a conductive contact on an upper surface of the shielding pattern,
wherein the conductive contact is electrically connected to the shielding pattern, and
wherein the conductive contact is configured to receive a ground voltage.

20. A three-dimensional semiconductor device comprising:
a substrate;
first semiconductor patterns on the substrate, wherein the first semiconductor patterns are spaced apart from each other in a first direction that is parallel to an upper surface of the substrate;
second semiconductor patterns on the substrate, wherein the second semiconductor patterns are spaced apart from the first semiconductor patterns in a second direction that is parallel to the upper surface of the substrate and intersects the first direction, and wherein the second semiconductor patterns are spaced apart from each other in the first direction;
first bit lines on first edge portions of the first semiconductor patterns, wherein the first bit lines extend in a third direction that is perpendicular to the upper surface of the substrate;
second bit lines on first edge portions of the second semiconductor patterns, wherein the second bit lines extend in the third direction, and wherein the first edge portions of the second semiconductor patterns face the first edge portions of the first semiconductor patterns in the second direction;
a word line that extends around at least one of the first semiconductor patterns, wherein the word line extends in the first direction;
a data storage pattern on second edge portions of the first semiconductor patterns, wherein the data storage pattern extends in the third direction, and wherein the second edge portions of the first semiconductor patterns are opposite to the first edge portions of the first semiconductor patterns in the second direction; and
a shielding pattern between the first bit lines and the second bit lines in the second direction,
wherein the shielding pattern includes first regions and second regions,
wherein the first regions of the shielding pattern are between the first bit lines and the second bit lines in the second direction,
wherein at least one of the second regions of the shielding pattern is between respective adjacent ones of the first regions of the shielding pattern in the first direction, and
where a width of the at least one of the second regions of the shielding pattern in the second direction is greater than a width of at least one of the first regions of the shielding pattern in the second direction.
